(19) United States
(12) Patent Application Publication
(10) Pub. No.: US 2008/0146033 A1
(43) Pub. Date: Jun. 19, 2008

(54) GAP-FILLING METHOD OF SEMICONDUCTOR DEVICE

(76) Inventor: Kyung-Min Park, Incheon (KR)

Correspondence Address: SHERR & NOURSE, PLLC, 620 HERNDON PARKWAY, SUITE 200, HERNDON, VA, 20170, US

(21) Appl. No.: 11/847,638

(22) Filed: Aug. 30, 2007

(30) Foreign Application Priority Data
Sep. 4, 2006 (KR) 10-2006-0084598

(51) Int. Cl. H01L 21/311

(52) U.S. Cl. 438/699; 257/E21.249

(57) ABSTRACT

A gap-filling method of a semiconductor device is realized without voids by providing the optimal deposition conditions based on DED conditions related to etching time, etching number and RF frequency. The method includes (a) depositing a first high-density plasma oxide film to fill some of a gap; (b) etching some of the first high-density plasma oxide film; (c) performing a gap-filling process by depositing a second high-density plasma oxide film on the first high-density plasma oxide film; and (d) repeating the sequential steps of (a), (b) and (c) three times.

This application claims the benefit under 35 U.S.C. §119 of Korean Patent Application No. 10-2006-0084598, filed Sep. 4, 2006, which is hereby incorporated by reference in its entirety.

### BACKGROUND

A high-density plasma chemical vapor deposition process is generally used as a method of fabricating an oxide dielectric film in semiconductor industrial fields.

With the trend to high-integration semiconductor devices, there is a requirement for performing oxide dielectric gap-filling without voids in Shallow Trench Isolation (STI) structures having an aspect ratio of 3 or more.

Voids are generated due to insufficient margins in photolithography and etching processes. As a result, large amounts of wafers are scrapped causing the reprocessing rate becomes high.

However, there are many difficulties in obtaining adequate margins of the respective processes. The simplest method being to enlarge the margin of the STI gap-filling in the fabrication process.

A high-density plasma chemical vapor deposition corresponds to a method of forming an oxide film by using deposition and sputtering together. A ratio of deposition to sputtering when forming the oxide film is referred to as “D/S” value, wherein “D/S=(net deposition rate+total sputtering rate)/total sputtering rate”.

The large value of “D/S” means that the deposition rate is exceedingly larger than the sputtering rate, whereby the deposition affects more than the sputtering of source gas in formation of the oxide film. In the meantime, the small value of “D/S” means that the sputtering rate of source gas is larger than the deposition rate, that is, the total deposition rate is small and the sputtering rate is large.

The small value of “D/S” prevents the STI gap from being completely filled by using sputtering, before completion of Bottom-Up Filling inside the STI when filling the STI gap. In this respect, a device having an aspect ratio of 3 or more is advantageous to this gap-filling.

However, if the value of “D/S” is too small, the STI pattern may be removed. Thus, it is important to use the appropriate value of “D/S” for the respective process.

When forming the oxide dielectric film using the high-density plasma chemical vapor deposition, the gap-filling is influenced by various elements, for example, plasma density, plasma uniformity, pressure, plasma potential, electron temperature, substrate temperature, and etc.

Since the source gas is decomposed by plasma which is generated by RF power, the density and uniformity of plasma are important elements on the gap-filling of the high-density chemical vapor deposition.

The vacuum level of chamber which stores reactant in the deposition is maintained at approximately 3 mTorr to approximately 5 mTorr. This is because the byproducts formed by sputtering are removed through a high-pressure pump. Thus, the byproducts have no bad effects on the Bottom-Up Filling.

If atoms having large radius, for example, Xe are added to the source gas, the plasma potential is decreased, so that the plasma density is decreased.

However, if atoms having small radius, for example, H₂ or He are added to the source gas, the plasma potential is increased, so that the plasma density is increased, which is advantageous to the STI gap-filling.

For the STI gap-filling in a device having an aspect ratio of 5 or more, a high-density plasma chemical vapor deposition is provided with the deposition and etching steps being separate from each other. In more detail, the oxide material is deposited by SiH₄/O₂, and then the overhang oxide materials formed at the sidewalls of the STI on the deposition step are removed by NF₃ gas to facilitate the following deposition.

However, due to the DED (deposition-etching-deposition) conditions such as gas flux, bias power and RF frequency in high-density plasma chemical vapor deposition, the voids can still occur in large numbers of wafers, whereby the wafers must be scrapped causing the reprocessing rate to become high.

### SUMMARY

Embodiments relate to a method for performing gap-filling method that includes (a) depositing a first high-density plasma oxide film to fill at least a portion of a gap; (b) etching at least a portion of the first high-density plasma oxide film; (c) performing a gap-filling process by depositing a second high-density plasma oxide film on the first high-density plasma oxide film; and (d) repeating the sequential steps of (a), (b) and (c) three times.

### DRAWINGS

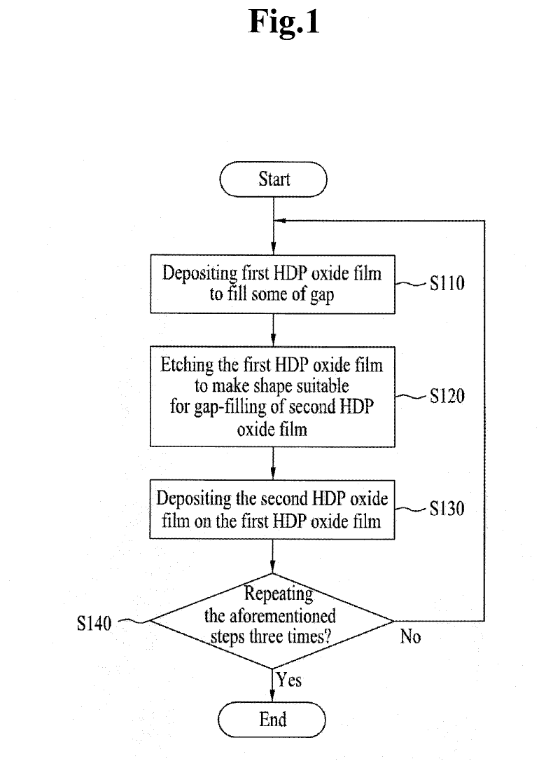

Example FIG. 1 is a flow chart of a gap-filling method of a semiconductor device using a DED method according to embodiments.

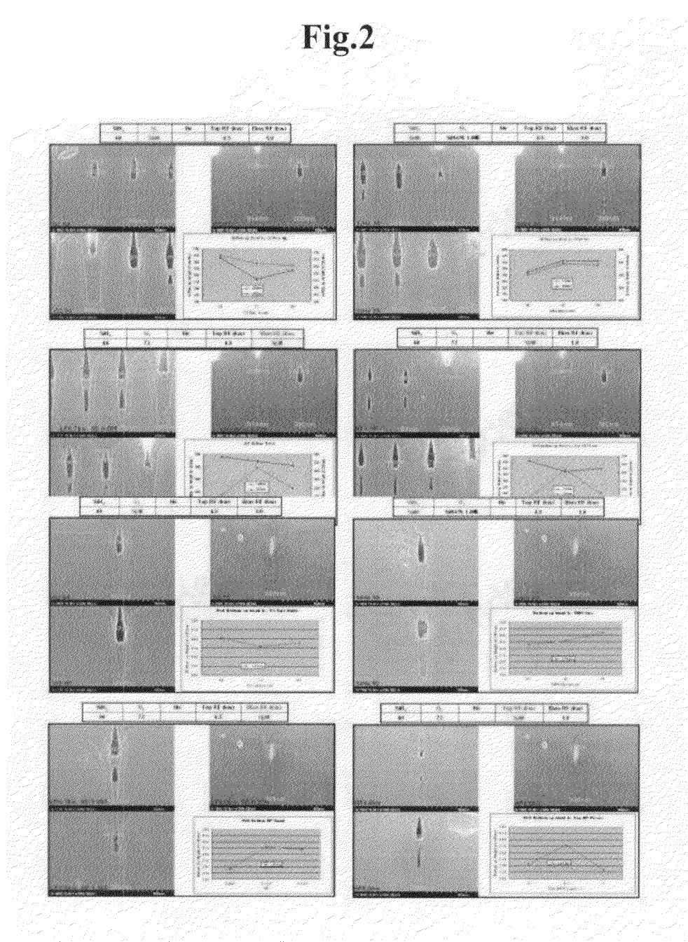

Example FIG. 2 is a view of a gap-filling capacity based on process parameters and split conditions.

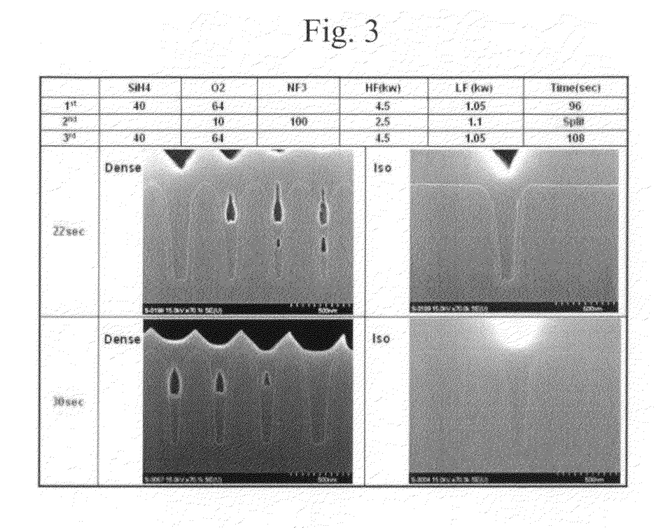

Example FIG. 3 is a view of a gap-filling capacity based on etching time.

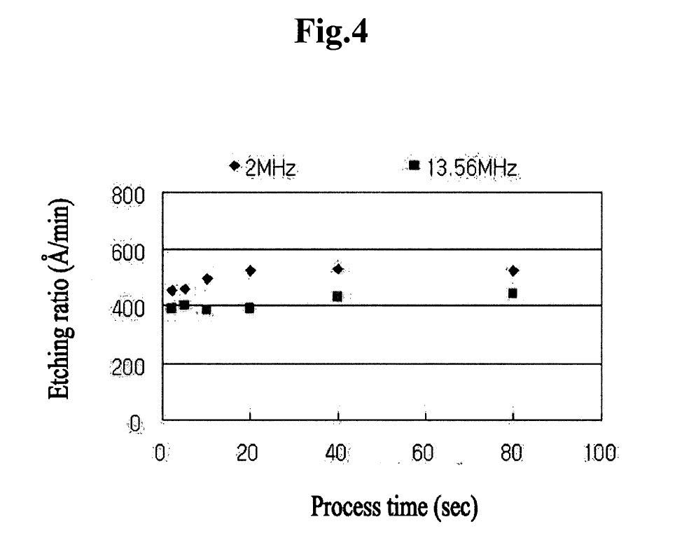

Example FIG. 4 is a graph of an etching ratio based on RF frequency.

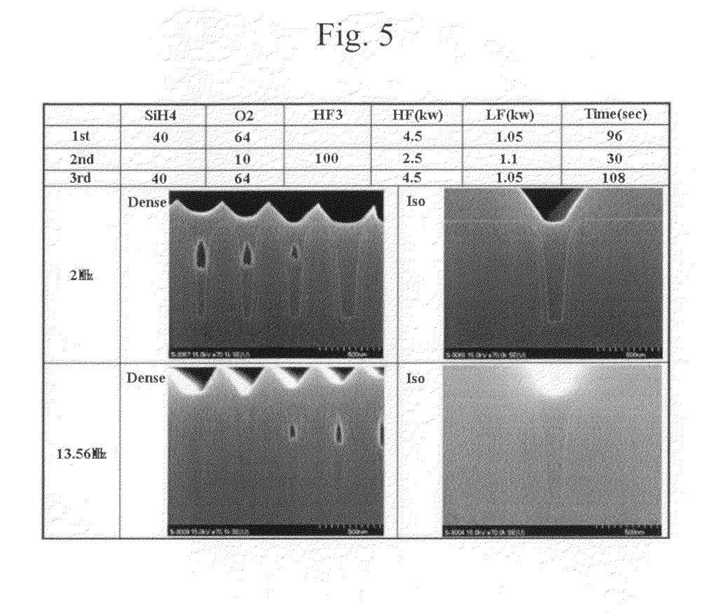

Example FIG. 5 is a view of a gap-filling capacity based on RF frequency.

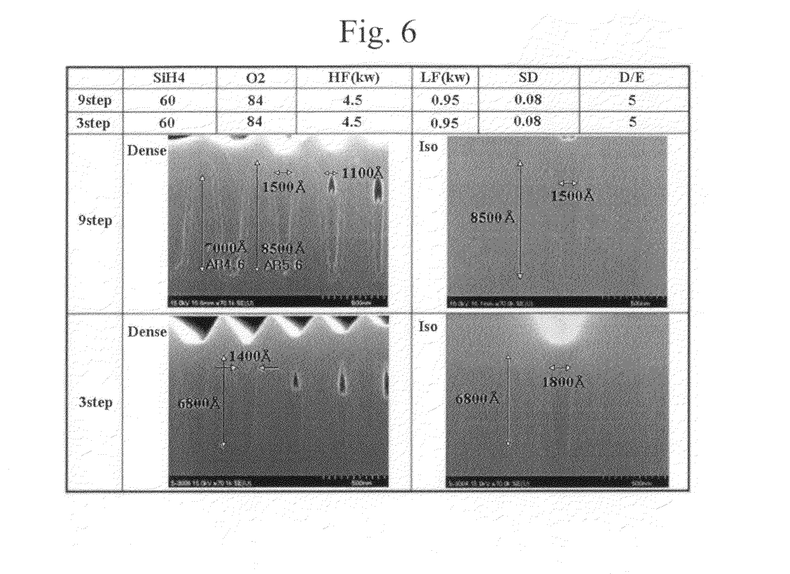

Example FIG. 6 is a view of a gap-filling capacity based on DED levels.

### DESCRIPTION

Hereinafter, a gap-filling method of a semiconductor device according to the embodiments herein will be described with reference to the accompanying drawings.

Example FIG. 1 is a flow chart of illustrating a gap-filling method of a semiconductor device using a DED method according to embodiments.

Referring to example FIG. 1, a gap-filling process using a DED method is comprised of a first deposition step (S110), an etching step (S120), and a second deposition step (S130). Then, the gap-filling process using these DED methods repeats the aforementioned sequential steps three times (S140).

In example FIG. 1, a first HDP oxide film is deposited to fill some of a gap in the first deposition step (S110).

The etching step (S120) etches some of the first HDP oxide film by using NF₃ gas. This etching step (S120) etches the first HDP oxide film to make a shape suitable for gap-filling of second HDP oxide film in the following process.

In the second etching step (S30), the second HDP oxide film is deposited on the first HDP oxide film. At this time, the HDP oxide film is a high-density plasma type oxide film which has a small thermal load and a good gap-filling property.

In detail, when carrying out the first deposition step (S110) to deposit the first HDP oxide film, the conditions for STI gap-filling are as follows.

That is, a gas flux of STI gap-filling is set as follows, for example, silane (SiH₄) of approximately 30 sccm to approximately 50 sccm, oxygen (O₂) of approximately 54 sccm to approximately 75 sccm, and bias power of approximately 1000 W to approximately 1300 W. Based on the change in the aforementioned conditions, a D/S value for STI gap-filling is controlled.

A vacuum level of chamber is maintained at approximately 3 mTorr on the deposition step, and a temperature of silicon (Si) substrate is maintained at about 700° C. on the gap-filling. Also, a ratio of sputtering to deposition (that is, SD value) is approximately 0.1 to approximately 0.14.

When carrying out the etching step (S120) to realize the shape suitable for the gap-filling of second HDP oxide film, an etching period of time is approximately 22 seconds to approximately 30 seconds, and a RF frequency is approximately 2 MHz to approximately 13.56 MHz.

When carrying out the second deposition step (S130) to deposit the second HDP oxide film on the first HDP oxide film, the conditions for STI gap-filling are as follows.

That is, a gas flux of STI gap-filling is set as follows, for example, silane (SiH₄) of approximately 30 sccm to approximately 50 sccm, oxygen (O₂) of approximately 54 sccm to approximately 75 sccm, and bias power of approximately 1000 W to approximately 1300 W. Based on the change in the aforementioned conditions, a D/S value for STI gap-filling is controlled. A vacuum level of chamber is maintained at approximately 3 mTorr on the deposition step, and a temperature of silicon (Si) substrate is maintained at approximately 700° C. on the gap-filling. Also, a ratio of sputtering to deposition (that is, SD value) is approximately 0.1 to approximately 0.14.

The following table 1 shows split conditions based on process parameters.

TABLE 1

| | | | SiH₄ | O₂ | He | D/R | | Time | | Pressure |
|---|---|---|---|---|---|---|---|---|---|---|
| Condition | | | (sccm) | (sccm) | (sccm) | (Å/min) | HF/LF (kw) | (sec) | SD | (mTorr) |
| 11 | DOE | 0-0 | 40 | 72 | | 2480 | 4.5/1.0 | 145 | 0.129 | 1.02 |
| | Split | 0-1 | 40 | 72 | | 2508 | 4.5/0.7 | 145 | 0.085 | 1.02 |
| | | 0-2 | 40 | 72 | | 2382 | 4.5/1.3 | 145 | 0.165 | 1.02 |
| | | 0-3 | 40 | 72 | | 2311 | 4.0/1.0 | 150 | 0.140 | 1.02 |
| | | 0-4 | 40 | 72 | | 2563 | 5.0/1.0 | 135 | 0.122 | 1.02 |
| | | 0-5 | 40 | 72 | 200 | 2395 | 4.5/1.0 | 145 | 0.110 | |
| | | 0-6 | 40 | 72 | 400 | 2453 | 4.5/1.0 | 145 | 0.095 | |
| | | 0-7 | 40 | 64 | | 2373 | 4.5/1.0 | 155 | 0.142 | |
| | | 0-8 | 40 | 80 | | 2425 | 4.5/1.0 | 150 | 0.129 | |
| | | 0-9 | 50 | 90 | | 3147 | 4.5/1.0 | 118 | 0.109 | |
| | | 0-10 | 30 | 54 | | 1771 | 4.5/1.0 | 207 | 0.172 | 0.82 |
| | | 0-11 | 40 | 72 | | 2108 | 4.5/1.0, CP80 | 170 | 0.156 | 1.02 |
| | | 0-12 | 30 | 54 | | 1850 | 4.5/0.7 | 199 | 0.124 | 0.82 |
| | | 0-13 | 30 | 54 | | 1936 | 4.5/0.4 | 189 | 0.058 | 0.82 |
| | | 0-14 | 50 | 75 | | 2776 | 4.5/1.3 | 174 | 0.142 | 1.21 |

Example FIG. 2 illustrates the gap-filling capacity based on the process parameters and split conditions.

The SD value of approximately 0.1 to approximately 0.14 has the greatest gap-filling capacity. As the ratio of SiH₄ to O₂ becomes lower, the gap-filling capacity becomes improved. Also, as a chuck position is increased, the gap-filling capacity is improved.

Example FIG. 3 illustrates the gap-filling capacity based on etching time.

As shown in example FIG. 3, the 1^{st} step performs the deposition for approximately 96 seconds under conditions in which SiH₄ is approximately 40 sccm, O₂ is approximately 64 sccm, HF is approximately 4.5 kW and LF is approximately 1.05 kW. The 2^{nd} step shows X-SEM photographs of split conditions for approximately 23 seconds or approximately 30 seconds when O₂ is approximately 10 sccm, NF₃ is approximately 100 sccm, HF is approximately 2.5 kW and LF is approximately 1.1 kW.

The gap-filling conditions of the 3^{rd} step are the same as those of the 1^{st} step.

As shown in example FIG. 3, for an isolated space, a gap-filling process having no voids can be realized in both the cases of 22 seconds and 30 seconds. However, for a dense space, when etching for 22 seconds, the voids are positioned more adjacent to the bottom of STI.

The etching amount based on the etching time under the DED conditions affects the gap-filling, and the appropriate etching time also has effects on achieving the gap-filling without the voids.

Example FIG. 4 is a graph of the etching ratio based on RF frequency. As shown in example FIG. 4, the initial value of etching when the RF frequency is approximately 2 MHz is more uniform and stable than the initial value of etching when the RF frequency is approximately 13.56 MHz. Thus, to realize the uniform etching on the entire area of wafer, the RF frequency of approximately 2 MHz is more appropriate than the RF frequency of approximately 13.56 MHz.

Example FIG. 5 is a view of the gap-filling capacity based on RF frequency.

As shown in example FIG. 5, the void generated when the RF frequency is approximately 2 MHz is positioned in the higher portion of the STI than the void generated when the RF frequency is approximately 13.56 MHz. That is, as the RF frequency becomes higher, the etching is more improved owing to the highly efficient decomposition of NF₃ gas plasma, which is advantageous to the gap-filling.

Example FIG. 6 is a view of the gap-filling capacity based on DED levels.

As shown in example FIG. 6, for the gap-filling, the DED level ‘9’ is more advantageous than the DED level ‘5’. That is, if the STI depth is increased, it is necessary to increase the number of the etching level based on the deposition, so as to realize the gap-filling without the voids. If the number of the etching level is small, it is difficult to remove the overhang generated on deposition, whereby the voids may occur.

As mentioned above, the gap-filling method of the semiconductor device according to these embodiments has the following advantages: the gap-filling method provides the optimal deposition conditions in relation with the etching time, the etching number and the RF frequency, whereby the voids are not generated during gap-filling of the semiconductor device, and the reprocessing for the device is unnecessary.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A gap-filling method comprising:
depositing a first high-density plasma oxide film to fill at least a portion of a gap;
etching at least a portion of the first high-density plasma oxide film;
performing a gap-filling process by depositing a second high-density plasma oxide film on the first high-density plasma oxide film; and
repeating said depositing, said etching, and said performing three times sequentially.

2. The method of claim 1, wherein the first high-density plasma oxide film is etched by NF₃ gas.

3. The method of claim 1, wherein the gap is part of an STI structure.

4. The method of claim 1, wherein depositing the first high-density plasma oxide uses SiH₄ and O₂.

5. The method of claim 4, wherein a ratio of SiH₄ to O₂ is between approximately 0.4 and approximately 0.9.

6. The method of claim 1, wherein depositing the first high-density plasma oxide comprises both deposition and sputtering.

7. The method of claim 6, wherein a ratio of sputtering to deposition is between approximately 0.1 and approximately 0.14.

8. The method of claim 4, wherein a flux of SiH₄ is between approximately 30 sccm and approximately 50 scccm and a flux Of O₂ is between approximately 54 sccm and approximately 75 sccm.

9. The method of claim 8, wherein a bias power is between approximately 1000 W and approximately 1300 W.

10. The method of claim 1, wherein depositing the first high-density plasma oxide occurs within a chamber pressurized at approximately 3 mTorr.

11. The method of claim 1, wherein depositing the second high-density plasma oxide uses SiH₄ and O₂.

12. The method of claim 11, wherein a ratio of SiH₄ to O₂ is between approximately 0.4 and approximately 0.9.

13. The method of claim 1, wherein depositing the second high-density plasma oxide comprises both deposition and sputtering.

14. The method of claim 13, wherein a ratio of sputtering to deposition is between approximately 0.1 and approximately 0.14.

15. The method of claim 11, wherein a flux of SiH₄ is between approximately 30 sccm and approximately 50 scccm and a flux of O₂ is between approximately 54 sccm and approximately 75 sccm.

16. The method of claim 15, wherein a bias power is between approximately 1000 W and approximately 1300 W.

17. The method of claim 1, wherein depositing the second high-density plasma oxide occurs within a chamber pressurized at approximately 3 mTorr.

18. The method of claim 1, wherein an etching time is between approximately 22 seconds and approximately 30 seconds.

19. The method of claim 18, wherein and a RF frequency used during etching is between approximately 2 and approximately 13.56 MHz.

20. The method of claim 1, wherein a temperature of the semiconductor substrate is maintained at approximately 700° C.
